(19) United States
(12) Patent Application Publication
(10) Pub. No.: US 2010/0271145 A1
(43) Pub. Date: Oct. 28, 2010

(54) CRYSTAL OSCILLATOR CIRCUIT AND ELECTRONIC DEVICE USING THE SAME

(75) Inventor: CHENG-YU WU, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/506,414

(22) Filed: Jul. 21, 2009

(30) Foreign Application Priority Data
Apr. 25, 2009 (CN) 200920302589.5

(51) Int. Cl. H03B 1/00

(52) U.S. Cl. 331/158

(57) ABSTRACT

A crystal oscillator circuit is connected between first and second oscillator pins of a chip and provides clock signals for the chip. The crystal oscillator circuit comprises a crystal, a first capacitor, a second capacitor and a third capacitor. The first capacitor is connected between the first and second oscillator pins of the chip. The second capacitor is connected between the first oscillator pin and ground. The third capacitor comprises one end connected to the second oscillator pin of the chip, and the other end grounded by way of the crystal.

### BACKGROUND

1. Technical Field

Embodiments of the present disclosure relate to a crystal oscillator circuit and an electronic device using the same.

2. Description of Related Art

Stable clock signals of electronic devices are often determined by resonance frequency provided by crystal oscillator circuits. However, precision of the resonance frequency is mainly dependent on practical load capacitance of the crystal oscillator circuit. Only when the practical load capacitance of the crystal oscillator circuit matches the value specified in the crystal's data sheet can the crystal oscillator circuit provide precise resonance frequency.

A commonly used crystal oscillator circuit comprises a quartz crystal connected between two oscillator pins of a chip, and two grounded external capacitors connected to the quartz crystal in parallel, respectively. Normally, the practical load capacitance is simply calculated from series combination of the two external capacitors. However, parasitic capacitance between the oscillator pins and ground increases when the crystal oscillator circuit operates at a high resonance frequency. Accordingly, the parasitic capacitance impacts the practical load capacitance of the crystal oscillator circuit and causes a deviation in the precise resonance frequency.

### BRIEF DESCRIPTION OF THE DRAWINGS

Many aspects of the embodiments can be better understood with references to the following drawings, wherein like numerals depict like parts, and wherein:

FIG. 1 is a circuit diagram of an electronic device of one embodiment of the present disclosure;

FIG. 2 is an equivalent circuit diagram of one embodiment of the electronic device of FIG. 1;

FIG. 3 is a schematic diagram showing impact of parasitic capacitance of oscillator pins of the crystal oscillator circuit on load capacitance; and;

FIG. 4 illustrates an equivalent resonance circuit of the crystal of the oscillator circuit of the present disclosure.

### DETAILED DESCRIPTION

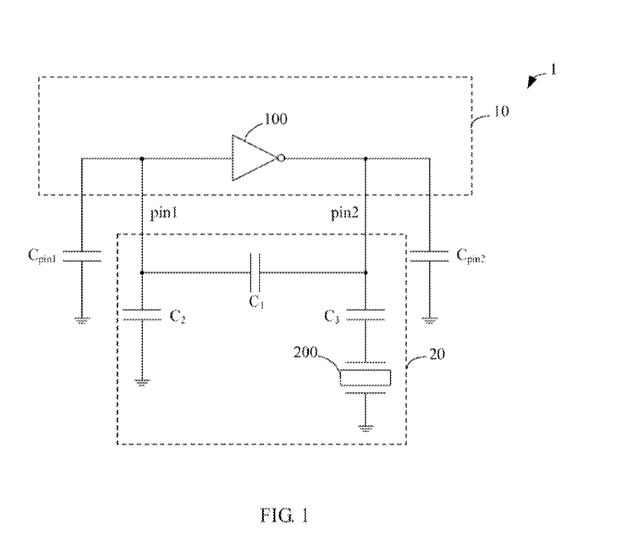

Referring to FIG. 1, a circuit diagram of an electronic device 1 of one embodiment of the present disclosure is shown. The electronic device 1 comprises a chip 10 and a crystal oscillator circuit 20. The crystal oscillator circuit 20 provides clock signals for the chip 10 of the electronic device 1, and comprises a crystal 200, and capacitors C₁, C₂, and C₃. In one embodiment, the chip 10 may be a single chip microcomputer.

In one embodiment, the chip 10 comprises a first oscillator pin Pin1, a second oscillator pin Pin2 and an inverting amplifier 100. Parasitic capacitors C_{Pin1} and C_{Pin2} are equivalent to parasitic capacitance of the first oscillator pin Pin1 and the second oscillator pin Pin2 to ground, respectively. The capacitors C₁, C₂ and C₃ are external capacitors. In one embodiment, the capacitor C₁ is connected between the first oscillator pin Pin1 and the second oscillator pin Pin2. The capacitor C₂ is connected between the first oscillator pin Pin1 and ground. The capacitor C₃ comprises one end connected to the second oscillator pin Pin2, and the other end grounded by way of the crystal 200.

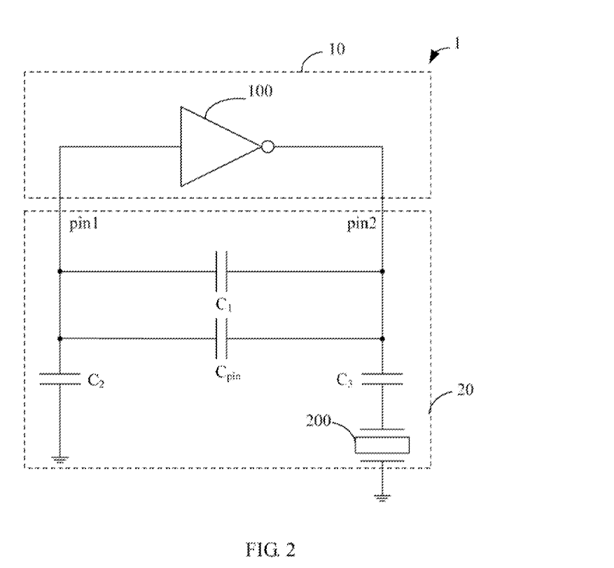

Referring to FIG. 2, an equivalent circuit of the crystal oscillator circuit 1 of FIG. 1 is shown. Parasitic capacitor C_{Pin} is an equivalent capacitor of series combination of the parasitic capacitors C_{Pin1} and C_{Pin2}. Capacitance of the parasitic capacitor C_{Pin} can be calculated by a following formula:

Cₚᵢₙ=(Cₚᵢₙ₁+Cₚᵢₙ₂)(Cₚᵢₙ₁×Cₚᵢₙ₂)

As shown in FIG. 2, the parasitic capacitor C_{Pin} and the first capacitor C₁ are connected in parallel between the first oscillator pin Pin1 and the second oscillator pin Pin2. The capacitor C₂ is connected between the first oscillator pin Pin1 and ground. The capacitor C₃ comprises one end connected to the second oscillator pin Pin2, and the other end grounded by way of the crystal 200. Load capacitor C_{L} of the crystal oscillator circuit 1 comprises the capacitors C₁, C₂, C₃ and C_{Pin}. Capacitance of the load capacitor C_{L} can be calculated by following formula:

C_{L}=[(C₁+Cₚᵢₙ)×C₂×C₃]/[(C₁+Cₚᵢₙ)×C₂+(C₁+Cₚᵢₙ+C₂)×C₃]

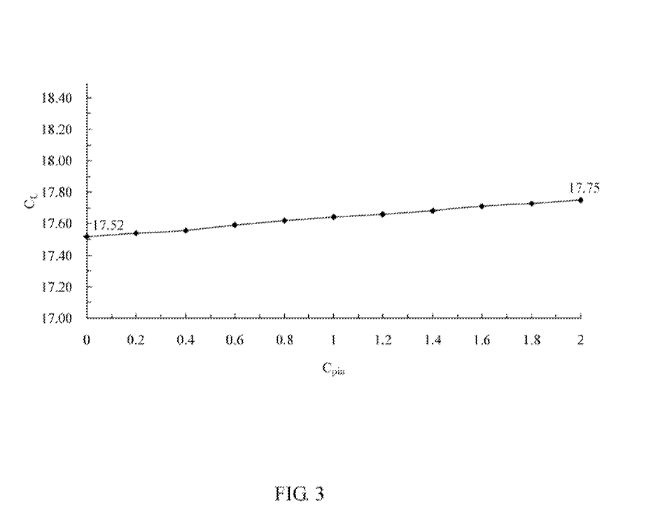

Referring to FIG. 3, impact of variation of the parasitic capacitor C_{Pin} on the load capacitor C_{L} is shown. In one embodiment, the capacitors C₁ and C₂ are both about 51 pF, and the capacitor C₃ is about 56 pF. As the capacitance of the parasitic capacitor C_{Pin} increases from 0 to 2 pF, the capacitance of the load capacitor C_{L} only increases 0.27 pF. Thus, the crystal oscillator circuit 1 efficiently decreases the impact of variation of the parasitic capacitor C_{Pin} on the load capacitor C_{L}, and reduces frequency deviation of the crystal oscillator circuit 1 accordingly.

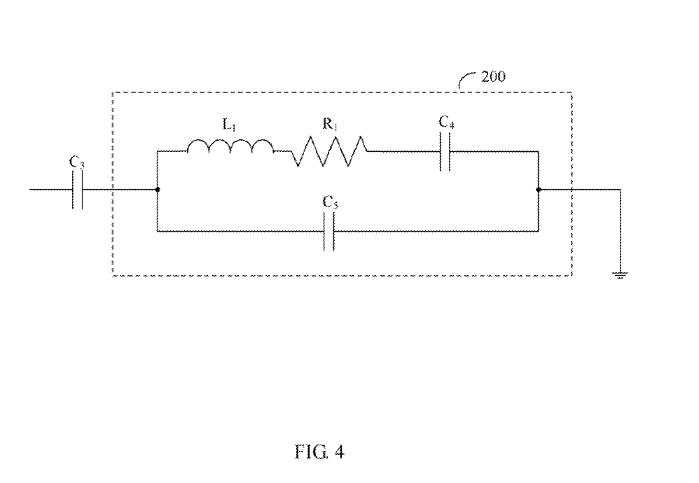

In one embodiment, the crystal 200 of the crystal oscillator circuit 1 comprises a quartz crystal or a ceramic resonator. In alternative embodiments, the crystal 200 of the oscillator circuit 1 may comprise an equivalent resonance circuit with similar function to a quartz crystal. Referring to FIG. 4, an equivalent resonance circuit of the quartz crystal 200 of the crystal oscillator 1 is shown. The equivalent resonance circuit comprises an inductor L1, a resistor R1, and capacitors C4 and C5. The inductor L1, the resistor R1, and the capacitor C4 are connected in series between the capacitor C3 of the crystal oscillator circuit 1 and ground. The capacitor C5 is connected between the capacitor C3 of the crystal oscillator circuit 1 and ground.

It is apparent that the present disclosure provides a crystal oscillator circuit with an improved layout of the external capacitors around the quartz crystal. The improved layout efficiently decreases the impact of variation of the parasitic capacitance on the load capacitance, and reduces frequency deviation of the crystal oscillator circuit.

It is believed that the present embodiments and their advantages will be understood from the foregoing description, and it will be apparent that various modifications, alterations and changes may be made thereto without departing from the spirit and scope of the invention or sacrificing all of its material advantages, the examples hereinbefore described merely being preferred or exemplary embodiments of the invention.

What is claimed is:

1. A crystal oscillator circuit connected between a first oscillator pin and a second oscillator pin of a chip, to provide clock signals for the chip, comprising:
a crystal;
a first capacitor connected between the first and second oscillator pins of the chip;
a second capacitor connected between the first oscillator pin of the chip and ground; and
a third capacitor with one end connected to the second oscillator pin of the chip, and the other end grounded by way of the crystal.

2. The crystal oscillator circuit as claimed in claim 1, wherein the crystal comprises a quartz crystal.

3. The crystal oscillator circuit as claimed in claim 1, wherein the crystal comprises a ceramic resonator.

4. The crystal oscillator circuit as claimed in claim 1, wherein the crystal comprises an equivalent resonance circuit.

5. The crystal oscillator circuit as claimed in claim 4, wherein the equivalent resonance circuit comprises an inductor, a resistor, a fourth capacitor and a fifth capacitor, wherein the inductor, the resistor and the fourth capacitor are connected in series between the third capacitor of the crystal oscillator and ground, and connected to the fifth capacitor in parallel.

6. An electronic device, comprising:
a chip comprising a first second oscillator pin and a second oscillator pin; and
a crystal oscillator circuit connected between the first and second oscillator pins of the chip, to provide clock signals for the chip, comprising:
a crystal;
a first capacitor connected between the first and second oscillator pins of the chip;
a second capacitor connected between the first oscillator pin of the chip and ground; and
a third capacitor with one end connected to the second oscillator pin of the chip, and the other end grounded by way of the crystal.

7. The electronic device as claimed in claim 6, wherein the crystal comprises a quartz crystal or a ceramic resonator.

8. The electronic device as claimed in claim 6, wherein the crystal comprises an equivalent resonance circuit.

9. The electronic device as claimed in claim 6, wherein the crystal comprises an equivalent resonance circuit.

10. The electronic device as claimed in claim 9, wherein the equivalent resonance circuit comprises an inductor, a resistor, a fourth capacitor and a fifth capacitor, wherein the inductor, the resistor and the fourth capacitor are connected in series between the third capacitor of the crystal oscillator and ground, and connected to the fifth capacitor in parallel.
